(19) United States
(12) Patent Application Publication
(10) Pub. No.: US 2026/0027805 A1
(43) Pub. Date: Jan. 29, 2026

(54) THERMALLY CONDUCTIVE SUBSTRATE BONDING INTERFACE

(71) Applicant: Tokyo Electron Limited, Tokyo (JP)

(72) Inventors: Andrew Tuchman, Albany, NY (US); Ayuta Suzuki, Albany, NY (US); Tek Po Rinus Lee, Albany, NY (US); Ilseok Son, Albany, NY (US)

(21) Appl. No.: 18/818,447

(22) Filed: Aug. 28, 2024

Related U.S. Application Data
(60) Provisional application No. 63/676,184, filed on Jul. 26, 2024.

(51) Int. Cl. H01L 23/00; B32B 9/04; H01L 25/065

(52) U.S. Cl. CPC H01L 24/27; B32B 9/04; H01L 24/29; H01L 24/32; H01L 24/83; B32B 2457/14; H01L 25/0657; H01L 2224/27845; H01L 2224/29019; H01L 2224/29084; H01L 2224/29124; H01L 2224/29187; H01L 2224/29193; H01L 2224/32145; H01L 2224/83013; H01L 2224/83193; H01L 2224/83896; H01L 2224/83948; H01L 2225/06513

(57) ABSTRACT

A bonded substrate structure includes a first substrate; a second substrate; and a bonding region bonding the first substrate to the second substrate. The bonding region includes an aluminum oxide bonding layer directly contacting an aluminum nitride layer, and a bonding interface between the aluminum oxide bonding layer and a bonding surface of the first substrate or the second substrate.

### CROSS-REFERENCE TO RELATED APPLICATIONS

This application claims priority to Provisional Application No. 63/676,184, filed on Jul. 26, 2024. The disclosure of the aforementioned application is hereby incorporated by reference in its entirety.

### TECHNICAL FIELD

The present invention relates generally to direct substrate bonding processes and, in particular embodiments, to structures and methods for forming bonded substrate structures that include a thermally conductive bonding interface.

### BACKGROUND

In the semiconductor industry, technological advancement has historically been achieved by scaling down generational technology nodes to ever smaller features and critical dimensions. In recent years, due to a variety of factors including increasing cost and complexity of nodes in nanometer ranges, heterogeneous integration of different semiconductor parts into advanced packages has become an increasingly important economic factor in the semiconductor industry. In particular, a need for ever greater numbers of transistors in applications that push performance limits, such as high-performance computing, artificial intelligence (AI)/machine learning (ML), machine vision, and autonomous vehicles and robots, among others, has made such advanced heterogeneous packages more economically important. The economic advantages of heterogeneous integration can include the ability to combine or mix semiconductor parts from different technology nodes into a single package. In this manner, the complexity or scope of portions of the single heterogeneous package that utilize the latest but most resource-intensive technology nodes, e.g., 7 nm or 3 nm nodes, can be reduced or minimized, which can lead to overall economic optimization.

Semiconductor industry has embraced 3D packaging to enable hybrid devices, such as that stack bonded die together and mix different technology nodes in a single final product for economic benefits. Such 3D ICs are often fabricated using direct bonding processes that produce multiple 3D ICs or chips in a single operation, which can then be sliced apart from the bonded structure.

### SUMMARY

A bonded substrate structure includes a first substrate; a second substrate; and a bonding region bonding the first substrate to the second substrate. The bonding region includes an aluminum oxide bonding layer directly contacting an aluminum nitride layer, and a bonding interface between the aluminum oxide bonding layer and a bonding surface of the first substrate or the second substrate.

A method of forming a bonded substrate structure includes forming an aluminum oxide bonding layer over an aluminum nitride layer of a first substrate; and directly bonding the aluminum oxide bonding layer of the first substrate to a bonding surface of a second substrate to form the bonded substrate structure.

A method of forming a bonded substrate structure includes forming an aluminum oxide bonding layer directly on a thermally conductive and electrically insulating layer of a first substrate; activating the aluminum oxide bonding layer using a nitrogen plasma; and directly bonding the aluminum oxide bonding layer of the first substrate to a bonding surface of a second substrate to form the bonded substrate structure; and annealing the bonded substrate structure at a temperature less than 400° C.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross-sectional view of an example bonded substrate structure with a first substrate bonded to a second substrate, where the first substrate has a first thermally conductive layer underlying a second thermally conductive layer in accordance with embodiments of the invention;

FIG. 2 illustrates a cross-sectional view of an example substrate that may be used to form bonded substrate structures described herein, the substrate having a thermally conductive layer of aluminum nitride underlying a thermally conductive layer or aluminum oxide in accordance with embodiments of the invention;

FIG. 3 illustrates a cross-sectional view of an example bonded substrate structure with a first substrate bonded to a second substrate, where the first substrate has a first thermally conductive layer underlying a second thermally conductive layer and the second substrate has a third thermally conductive layer underlying a fourth thermally conductive layer in accordance with embodiments of the invention;

FIGS. 4A and 4B illustrate a substrate during various stages of an example bonding process that may be used to form bonded structures described herein where FIG. 4A shows a substrate with a thermally conductive layer of aluminum nitride formed thereon and FIG. 4B shows the substrate after a layer formation step during which a thermally conductive layer of aluminum oxide is formed over the first thermally conductive layer as a bonding layer in accordance with embodiments of the invention;

FIGS. 5A and 5B illustrate a substrate during various stages of an example bonding process that may be used to form bonded structures described herein where FIG. 5A shows a substrate after a layer formation step during which a thicker aluminum oxide layer is formed and FIG. 5B shows the substrate after a planarization step that planarizes the thicker aluminum oxide layer to form an aluminum oxide bonding layer in accordance with embodiments of the invention;

FIG. 6 illustrates a substrate after a direct bonding step of an example bonding process that may be used to form bonded structures described herein where an aluminum oxide bonding layer of the substrate is bonded to an additional aluminum oxide bonding layer of a second substrate during the bonding step in accordance with embodiments of the invention;

FIG. 7 illustrates a cross-sectional view of an example bonded substrate structure with a bonding region that includes an aluminum oxide region between two aluminum nitride regions in accordance with embodiments of the invention;

FIG. 8 illustrates a cross-sectional view of an example bonded substrate structure with a bonding region that includes an aluminum oxide region between a silicon-containing region and an aluminum nitride region in accordance with embodiments of the invention;

FIG. 9 illustrates a cross-sectional view of an example bonded substrate structure with a bonding region that includes an aluminum oxide region between a silicon oxide region and an aluminum nitride region in accordance with embodiments of the invention;

FIG. 10 illustrates a cross-sectional view of another example bonded substrate structure with a bonding region that includes an aluminum oxide region between two aluminum nitride regions in accordance with embodiments of the invention;

FIG. 11 illustrates an example method of forming a bonded substrate structure in accordance with embodiments of the invention.

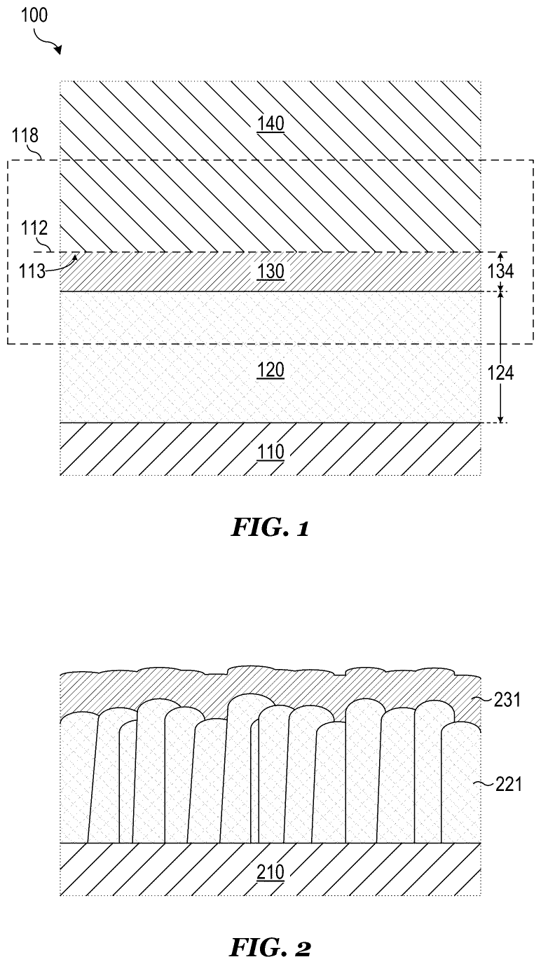

It should be understood that the dimensions such as thicknesses of the layers shown in FIGS. 1-10 are not necessarily drawn to scale. The relative thicknesses may vary in different embodiments to achieve desired thermal and bonding properties.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

The present disclosure relates generally to structures and methods for forming bonded substrate structures that include a thermally conductive bonding interface, such as direct wafer bonding processes in semiconductor manufacturing. More specifically, it relates to techniques for integrating thermally conductive materials like aluminum nitride and diamond into direct bonding processes while achieving good bonding strength and quality.

As semiconductor devices become more densely integrated, heat dissipation becomes an increasingly critical challenge, particularly for stacked or 3D integrated devices. In such stacked structures, the bonding interface between wafers or dies can act as a thermal bottleneck, trapping heat within device layers. Traditional bonding dielectric materials like silicon oxide and silicon carbonitride, while providing good electrical insulation and bonding properties, have relatively low thermal conductivity. This can lead to localized heating and temperature build-up that negatively impacts device performance and reliability. It has been challenging to identify alternative materials that have the desired electrically insulation and thermal conduction while still be compatible with direct substrate bonding processes (such as having sufficiently low surface roughness).

Various types of direct bonding processes exist. One type of direct bonding process is fusion bonding, where two substrate surfaces are brought into intimate contact at room temperature and then annealed at higher temperatures (e.g., 800-1200° C.) to form strong covalent bonds. The annealing temperature may be lowered using surface activation techniques (e.g., exposing the bonding surface to plasma). Surface activation may allow strong covalent bonds to be formed at annealing temperatures less than 400° C., for example. Fusion bonding may be used in a variety of applications, including silicon-on-insulator (SOI) fabrication, microelectromechanical devices (MEMS), nanoelectromechanical devices (NEMS), and others. Another similar type of direct bonding process is known as hybrid bonding and combines aspects of fusion bonding with metal-to-metal bonding. Specifically, hybrid bonding simultaneous bonds dielectric materials and metal materials, such as interconnects. Hybrid bonding may be used in applications where electrical contact between the two wafers is desired, such as for three-dimensional integration (3DI) in advanced packaging applications.

Surface roughness significantly impacts the effectiveness of the direct bonding process. For example, rougher surfaces decrease contact area between the substrates which in turn decreases bond strength and allows air to be trapped creating voids and weak spots in the bonding interface. Voids may also compromise the mechanical, thermal, and electrical properties of the bonded structure. To compensate for higher surface roughness, additional energy may be applied during the bonding process, such as by increasing the bonding temperature or applying more bonding pressure. However, higher temperature and pressure can damage structures in the substrates as well as the substrates themselves.

There is a need for bonding interfaces that provide high thermal conductivity to more effectively dissipate heat, while maintaining the electrical insulation and strong bonding characteristics required for wafer-to-wafer (W2 W) and die-to-wafer (D2 W) bonding processes. Materials like aluminum nitride and diamond offer promising thermal properties for this application, but present challenges in terms of bonding behavior when integrated into conventional direct bonding flows. For example, it can be difficult to form films out of thermally conductive materials, such as aluminum nitride and diamond, with sufficiently smooth surfaces for direct substrate bonding processes. Planarization processes, such as chemical mechanical polishing (CMP), ion milling, gas cluster ion beam (GCIB), and others, may be used to smooth the surfaces of the wafers prior to bonding. Yet, many materials that cannot be formed with sufficiently smooth surfaces but would otherwise be desirable to use at the bonding interface, such as aluminum nitride and diamond, are also incompatible with planarization processes, sometimes even becoming rougher during attempted planarization.

In various embodiments, the present disclosure describes methods for forming wafer bonding interfaces incorporating thermally conductive materials like aluminum nitride, while achieving the surface quality and bonding strength needed for reliable wafer bonding. The approach involves depositing aluminum nitride films, modifying their surface properties, and using thin aluminum oxide layers to mediate bonding. Various embodiments may include steps for planarizing rough aluminum nitride surfaces. The resulting bonding interfaces may provide improved thermal conductance compared to conventional bonding dielectrics, potentially enabling better heat dissipation in advanced semiconductor devices.

FIG. 1 illustrates a cross-sectional view of an example bonded substrate structure with a first substrate bonded to a second substrate, where the first substrate has a first thermally conductive layer underlying a second thermally conductive layer in accordance with embodiments of the invention.

Referring to FIG. 1, a bonded substrate structure 100 includes a substrate 110 (i.e., a first substrate) that is bonded to a second substrate 140 using a bonding region 118 that includes a first thermally conductive layer 120 and a second thermally conductive layer 130 (that is a different material than the first thermally conductive layer 120). For example, before the substrate 110 and the second substrate 140 are bonded together, the first thermally conductive layer 120 may be formed on the substrate 110 and the second thermally conductive layer 130 may be formed over the first thermally conductive layer 120. In one embodiment, the second thermally conductive layer 130 is formed directly on the first thermally conductive layer 120.

The inclusion of the first thermally conductive layer 120 and the second thermally conductive layer 130 in the bonding region 118 may increase the thermal conductivity of the bonded substrate structure 100 compared to conventional bonded substrate structures. In some embodiments, the first thermally conductive layer 120 and the second thermally conductive layer 130 are also electrically insulating materials. Some examples of electrically insulating materials that are more thermally conductive than materials used in conventional bonded substrate structures include aluminum nitride (AlN), aluminum oxide (Al₂O₃), diamond, graphene, and others.

In various embodiments, this first thermally conductive layer 120 may comprise a material with high thermal conductivity. In some embodiments, the first thermally conductive layer 120 may have a thermal conductivity greater than 10 W/m·K, and greater than 50 W/m·K in one embodiment. The cross-plane thermal conductivity (out-of-plane thermal conductivity κ⊥) of the first thermally conductive layer 120 may also be high, such as greater than about 10 W/m. K. The second thermally conductive layer 130 may be selected to have smoother surface than the first thermally conductive layer 120, but may have a lower thermal conductivity as a tradeoff (although still higher thermal conductivity than many materials used in conventional bonding processes). In one embodiment, the first thermally conductive layer 120 is an aluminum nitride layer. In another embodiment, the first thermally conductive layer 120 is a diamond layer.

In one embodiment, the second thermally conductive layer 130 is an aluminum oxide layer. In various embodiments, the bonding region 118 includes at least one aluminum nitride layer and at least one aluminum oxide bonding layer.

The second thermally conductive layer 130 acts as a bonding layer for the substrate 110 and is brought into contact with a bonding surface 113 of the second substrate 140 at a bonding interface 112, which is depicted as a dashed line. That is, the bonding interface 112 represents the location at which the substrate 110 and the second substrate 140 are brought together to be bonded, but does not necessarily represent a physical structure of the bonded substrate structure 100. For example, when the bonding surface 113 is the same material as the second thermally conductive layer 130, there may or may not be a physical bonding interface after the formation of chemical bonds between the second thermally conductive layer 130 and the bonding surface 113, such as after an annealing process.

As shown, the first thermally conductive layer 120 has a thermally conductive layer thickness 124 while the second thermally conductive layer 130 has a bonding layer thickness 134. Although the thermally conductive layer thickness 124 and the bonding layer thickness 134 may be selected to be any desirable values, the thermally conductive layer thickness 124 is thicker than the bonding layer thickness 134 in various embodiments. For example, the first thermally conductive layer 120 may be a material with high thermal conductivity that is difficult to bond directly to the bonding surface 113, such as aluminum nitride or diamond (e.g., because of high surface roughness). Increasing the thermally conductive layer thickness 124 of such a material may advantageously increase the thermal conductivity of the bonding region 118 and improve heat dissipation in the bonded substrate structure 100.

In various embodiments, the thermally conductive layer thickness 124 is greater than about 25 nm. In some embodiments, the thermally conductive layer thickness 124 of the first thermally conductive layer 120 is greater than about 100 nm and less than about 500 nm. In some embodiments, the thermally conductive layer thickness 124 is between about 50 nm and 300 nm. In various embodiments, the bonding layer thickness 134 of the second thermally conductive layer 130 is less than about 10 nm (such as between about 1 nm and about 10 nm) and is less than about 5 nm (such as between about 1 nm and about 5 nm) in some embodiments.

The second thermally conductive layer 130 may then have lower thermal conductivity (but still higher than materials used in conventional bonded substrate structures) and improved bonding characteristics relative to the first thermally conductive layer 120. For example, when the second thermally conductive layer 130 is aluminum oxide, the second thermally conductive layer 130 may be a smoother surface and already include oxygen, allowing for improved bond strength between the substrate 110 and the second substrate 140 compared to achievable bond strengths without the second thermally conductive layer 130.

The first thermally conductive layer 120 may be formed so that it is disposed on the substrate 110 using various techniques. In one embodiment, the first thermally conductive layer 120 is formed using a physical vapor deposition (PVD) process. In another embodiment, the first thermally conductive layer 120 is formed using a chemical vapor deposition (CVD) process. In some embodiments, the first thermally conductive layer 120 is formed using a plasma-enhanced CVD (PE-CVD) process.

The second thermally conductive layer 130 may be formed over the first thermally conductive layer 120 using similar or different techniques. In one embodiment, the second thermally conductive layer 130 is formed using atomic layer deposition (ALD). For example, ALD may be have the advantage of affording a high degree of control during deposition and enabling the second thermally conductive layer 130 to be very thin (e.g., on the order of nanometers or even thinner), which may in turn improve the thermal performance of the bonded substrate structure 100. In other embodiments, the second thermally conductive layer 130 may be formed using a different technique, such as a CVD process or a PE-CVD process. While the first thermally conductive layer 120 could also be formed with an ALD process, it may be less desirable or infeasible due to the desire for the first thermally conductive layer 120 to be thick to increase thermal conductivity.

The substrate 110 may be any suitable substrate. For example, the substrate 110 may be an insulating, conducting, or semiconducting substrate with one or more layers disposed thereon (e.g., including device layers with active components, metallization layers with interconnects, etc.). For example, the substrate 110 may include a device layer and a protection layer, and the first thermally conductive layer 120 (e.g., an aluminum nitride layer) may be deposited over the protection layer. The second substrate 140 may also include various layers and structures. In one embodiment, the second substrate 140 includes active components in a device layer and metal interconnect layers. In one embodiment, both the substrate 110 and the second substrate 140 include active components in a respective device layers.

The substrate 110 may be a semiconductor wafer, such as a silicon wafer, including various layers, structures, and devices (e.g., forming integrated circuits). In one embodiment, the substrate 110 includes silicon. In still another embodiment, the substrate 110 includes silicon carbide (SiC). In still another embodiment, the substrate 110 includes silicon germanium (SiGe). In still yet another embodiment, the substrate 110 includes gallium arsenide (GaAs). Of course, many other suitable materials, semiconductor or otherwise, may be included in the substrate 110 as may be apparent to those of skill in the art. For example, the substrate 110 may be a gallium nitride (GaN) substrate, an SOI substrate, a silicon on semiconductor substrate, such as a Si on GaN substrate, a glass substrate, and many others. Similarly, the second substrate 140 may also be any suitable substrate, and may be the same or different from the substrate 110.

In various embodiments, the second substrate 140 is similar to the substrate 110 in that it may also have one or more thermally conductive layers formed thereon. In one embodiment, the bonding surface 113 of the second substrate 140 is aluminum oxide. In another embodiment, the bonding surface 113 of the second substrate 140 is aluminum nitride. In other embodiments, the bonding surface 113 of the second substrate 140 is a silicon-containing surface, such as silicon (Si) or silicon oxide (SiO₂). However, the bonding surface 113 may also be a silicon-containing surface that includes other silicon-containing materials, such as silicon nitride (Si₃N₄), SiC, silicon carbonitride (SiCN), and others.

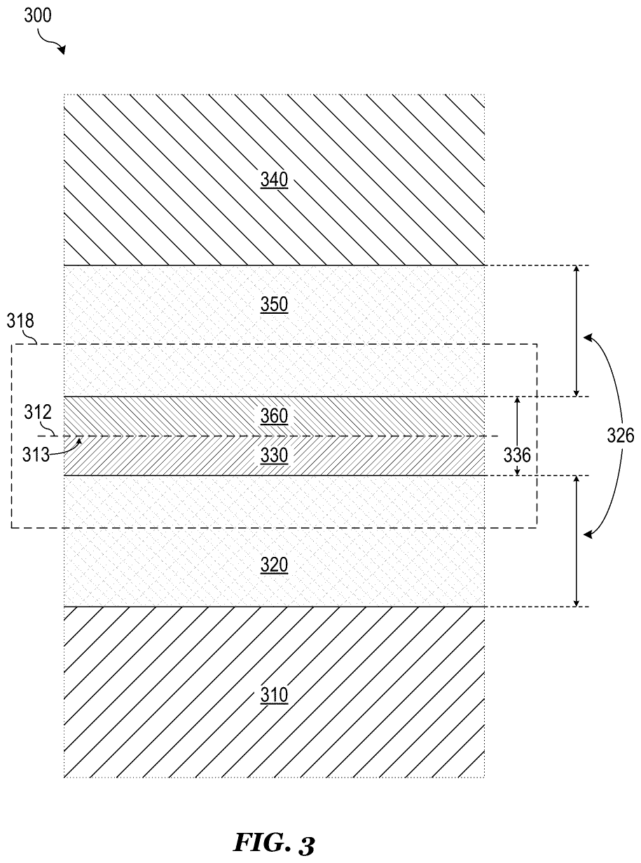

FIG. 2 illustrates a cross-sectional view of an example substrate that may be used to form bonded substrate structures described herein, the substrate having a thermally conductive layer of aluminum nitride underlying a thermally conductive layer of aluminum oxide in accordance with embodiments of the invention.

Referring to FIG. 2, a substrate 210 includes an aluminum nitride layer 221 (a specific example of a thermally conductive layer, such as the first thermally conductive layer 120 of FIG. 1) disposed thereon. An aluminum oxide bonding layer 231 is formed (e.g., deposited using a suitable technique, such as ALD, CVD, PE-CVD, etc.). The aluminum oxide bonding layer 231 is a specific example of a thermally conductive layer, such as the second thermally conductive layer 130 of FIG. 1, for example. It should be noted that here and in the following a convention has been adopted for brevity and clarity wherein elements adhering to the pattern [x10] where ‘x’ is the figure number may be related implementations of a substrate in various embodiments. For example, the substrate 210 may be similar to the substrate 110 except as otherwise stated. An analogous convention has also been adopted for other elements as made clear by the use of similar terms in conjunction with the aforementioned numbering system.

The aluminum nitride layer 221 (e.g., an aluminum nitride film) may have a certain structure that contributes to properties such as thermal conductivity and surface roughness. For example, the aluminum nitride layer 221 may have a crystalline structure or multiple regions with a crystalline structure. In some embodiments, the aluminum nitride layer 221 has a columnar polycrystalline structure (as shown), which may contribute to its high thermal conductivity properties. However, the crystalline and polycrystalline structures (such as the columnar polycrystalline structure) may also contribute to increased surface roughness.

The aluminum oxide bonding layer 231 reduces the surface roughness of the aluminum nitride layer 221, which may have the advantage of increasing the bonding capability of the substrate 210 to another substrate. Although aluminum nitride is provided as an example here, it is worth noting that the aluminum oxide bonding layer 231 may also decrease the surface roughness of other thermally conductive materials that could be used instead of the aluminum nitride layer 221, such as diamond, for example.

Additionally, the aluminum oxide bonding layer 231 already includes oxygen, which may advantageously avoid the use of oxygen plasma during a surface activation step. For example, in the absence of the aluminum oxide bonding layer 231, an oxygen plasma activation step may be performed to try and incorporate oxygen at the surface along with the aluminum and nitrogen. However, by using the aluminum oxide bonding layer 231, oxygen is already present. When included an activation step may use nitrogen plasma to create dangling bonds, which may then be followed with a rinse step, (e.g., with deionized (DI) water) to create hydrophilic hydroxyl groups, for example.

FIG. 3 illustrates a cross-sectional view of an example bonded substrate structure with a first substrate bonded to a second substrate, where the first substrate has a first thermally conductive layer underlying a second thermally conductive layer and the second substrate has a third thermally conductive layer underlying a fourth thermally conductive layer in accordance with embodiments of the invention. The bonded substrate structure of FIG. 3 may be a specific example of other bonded substrate structures described herein, such as the bonded substrate structure of FIG. 1, for example. Similarly labeled elements may be as previously described.

Referring to FIG. 3, a bonded substrate structure 300 includes a substrate 310 (i.e., a first substrate) that is bonded to a second substrate 340 using a bonding region 318 that includes a first thermally conductive layer 320 and a second thermally conductive layer 330. The bonded substrate structure 300 is a specific example of the bonded substrate structure 100 of FIG. 1 in which the second substrate 340 also includes thermally conductive layers. Specifically, the second substrate 340 includes a third thermally conductive layer 350 and a fourth thermally conductive layer 360 that acts as a bonding layer of the second substrate 340. In this specific example, the fourth thermally conductive layer 360 forms a bonding surface 313 that is brought in contact with the second thermally conductive layer 330 at a bonding interface 312.

As previously discussed, the substrate 310 has a thermally conductive layer thickness that may be thicker than a bonding layer thickness. In this specific example, the second substrate 340 also has a thermally conductive layer thickness that may be thicker than a bonding layer thickness (whether the same or different than those of the substrate 310). The thicknesses of the second thermally conductive layer 330 and the fourth thermally conductive layer 360 combine to form a total bonding layer thickness 336. In various embodiments, the total bonding layer thickness 336 is less than about 10 nm and is less than about 5 nm in some embodiments.

Similarly, the first thermally conductive layer 320 and the third thermally conductive layer 350 combine to form a total thermally conductive layer thickness 326. In various embodiments, the total thermally conductive layer thickness 326 is greater than about 50 nm, and is greater than about 200 nm in some embodiments. The total thermally conductive layer thickness 326 may also be even higher such as greater than about 500 nm, greater than about 1000 nm, and higher.

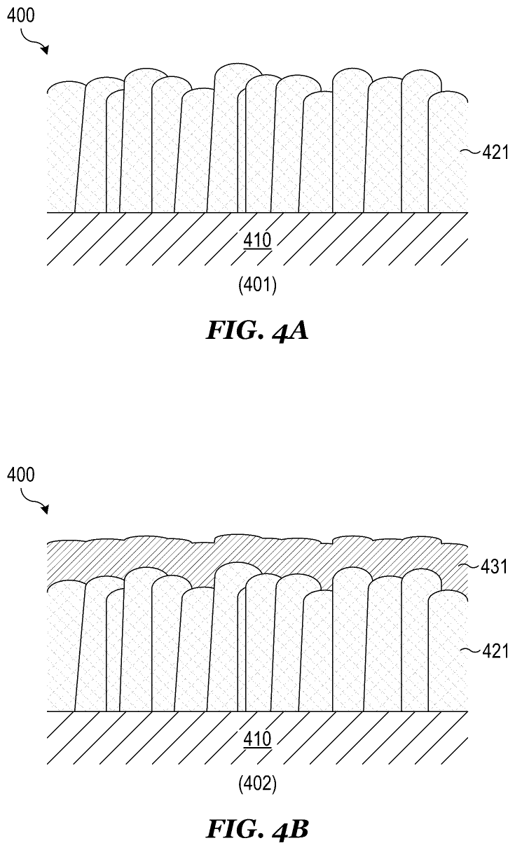

Embodiments of this application may be applied to wafer to wafer (W2 W) bonding or die to wafer (D2 W) bonding techniques using direct bonding. Certain aspects of the process flow will be described using FIGS. 4A-4B, 5A-5B, and 6 in which a substrate is illustrated during various stages of a bonding process.

FIGS. 4A and 4B illustrate a substrate during various stages of an example bonding process that may be used to form bonded structures described herein where FIG. 4A shows a substrate with a thermally conductive layer of aluminum nitride formed thereon and FIG. 4B shows the substrate after a layer formation step during which a thermally conductive layer of aluminum oxide is formed over the first thermally conductive layer as a bonding layer in accordance with embodiments of the invention.

Referring to FIG. 4A, a direct bonding process 400 begins with a substrate 410 that has an aluminum nitride layer 421 disposed thereon. For example, the aluminum nitride layer 421 may be formed during a layer formation step 401 as part of the direct bonding process 400. Alternatively, the aluminum nitride layer 421 may already exist on the substrate 410 at the start of the direct bonding process 400. At this stage, the substrate 410 may include various device regions, metallization layers, passivation layers, and/or protection layers (not shown) that have been formed using standard semiconductor fabrication processes prior to the formation of the aluminum nitride layer 421.

The aluminum nitride layer 421 may be deposited using various deposition techniques. In one embodiment, the aluminum nitride layer 421 is deposited using a PVD technique (e.g., a medium temperatures, such as about 200° C.), such as a sputtering process. In some embodiments, the deposition may be performed at low temperatures, for example, at about 25° C., or between about 25° C. and about 300° C. in various embodiments. Various additional steps may be performed to improve the thermal conductivity of the aluminum nitride layer 421, such as a thermal anneal (e.g., at between about 200° C. to about 400° C.) after the deposition of the aluminum nitride layer 421. Other techniques may also be used to form the aluminum nitride layer 421, such as CVD, PE-CVD, etc.

At this stage of the process, the surface of the aluminum nitride layer 421 may have a certain degree of roughness. The surface roughness of the aluminum nitride layer 421 may increase as its thickness increases. This relationship between thickness and roughness may present difficulty for subsequent bonding steps, particularly when thicker layers are desired for their enhanced thermal conductivity properties. For example, the root mean square (RMS) surface roughness may increase from about 1-2 Rq for thinner layers to about 3-4 Rq or more for thicker layers. The inventors found that performing a chemical mechanical polishing on an aluminum nitride layer resulted in increased surface roughness.

Referring now to FIG. 4B, an aluminum oxide bonding layer 431 is formed on the aluminum nitride layer 421 during a layer formation step 402. The formation of the aluminum oxide bonding layer 431 may be performed using various techniques. In one embodiment, the layer formation step 402 uses an ALD process to deposit the aluminum nitride layer 421. An ALD process may allow for precise control of the layer thickness and uniformity. In another embodiment, the layer formation step 402 uses a CVD process. In various embodiments, the thickness of the aluminum oxide bonding layer 431 is thinner than the aluminum nitride layer 421, which may be consistent with a desired balance between thermal conductivity and achievable bond strength.

The aluminum oxide bonding layer 431 decreases the surface roughness (i.e., the surface of the aluminum oxide bonding layer 431 is smoother than that of the aluminum nitride layer 421 and is more suitable for subsequent bonding steps). In some embodiments, additional steps (such as a planarization) may be performed on the aluminum oxide bonding layer 431 to achieve the smoother surface. In other embodiments, the deposition process itself results in a smoother surface. The aluminum oxide bonding layer 431 may have an RMS surface roughness that is suitable for direct bonding processes, for example, less than about 0.5 nm, or between about 0.01 nm and about 0.7 nm. The surface roughness of the aluminum oxide bonding layer 431 may be sufficiently low to advantageously enable strong and void-free bonding in subsequent steps.

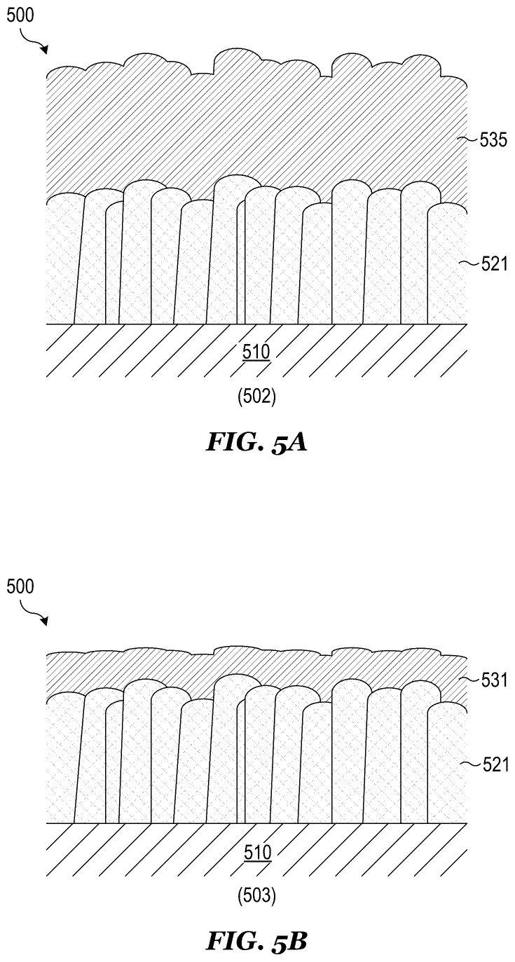

FIGS. 5A and 5B illustrate a substrate during various stages of an example bonding process that may be used to form bonded structures described herein where FIG. 5A shows a substrate after a layer formation step during which a thicker aluminum oxide layer is formed and FIG. 5B shows the substrate after a planarization step that planarizes the thicker aluminum oxide layer to form an aluminum oxide bonding layer in accordance with embodiments of the invention.

Referring to FIG. 5A, a direct bonding process 500 may include a layer formation step 502 during which a thick aluminum oxide layer 535 is formed (e.g., deposited, such as with CVD or ALD) on an aluminum nitride layer 521 that is disposed on a substrate 510. For example, the substrate 510 prior to layer formation step 502 may be similar to the substrate 410 at the beginning of the direct bonding process 400. While the thick aluminum oxide layer 535 may be smoother than the aluminum nitride layer 521, it may also substantially retain the topography of the aluminum nitride layer 521 (as shown). However, the thick aluminum oxide layer 535 may have the advantage of being more amenable to a planarization process than the aluminum nitride layer 521.

Turning now to FIG. 5B, the thick aluminum oxide layer 535 is smoothed during a planarization step 503 (which also may result in decreasing its thickness, as shown) to form an aluminum oxide bonding layer 531. In one embodiment, the planarization step 503 includes a CMP process. However, other planarization techniques may be used instead of or in addition to a CMP process. In one embodiment, the planarization step 503 includes an ion milling process. In one embodiment, the planarization step 503 includes a GCIB process. The planarization step 503 may result smoother bonding layer. For example, the aluminum oxide bonding layer 531 may be similar to the aluminum oxide bonding layer 431 of the direct bonding process 400.

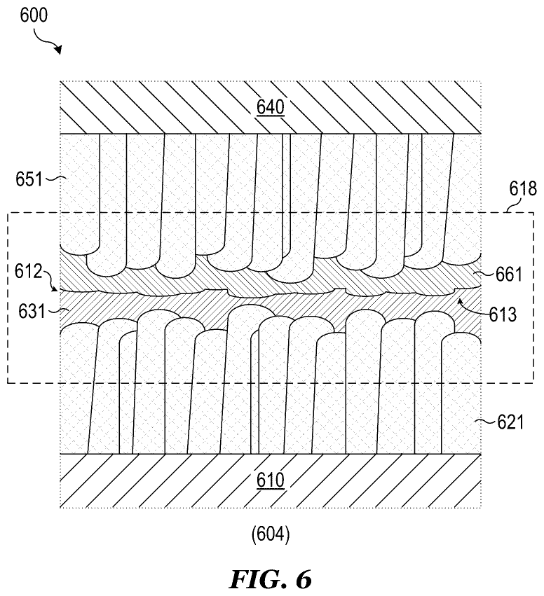

FIG. 6 illustrates a substrate after a direct bonding step of an example bonding process that may be used to form bonded structures described herein where an aluminum oxide bonding layer of the substrate is bonded to an additional aluminum oxide bonding layer of a second substrate during the bonding step in accordance with embodiments of the invention.

Referring to FIG. 6, a direct bonding process 600 ends with a direct bonding step 604 during which a substrate 610 is bonded to a second substrate 640 using a bonding region 618. In this specific example, both the substrate 610 and the second substrate 640 may have been formed using the process steps described in FIGS. 4A and 4B and/or in FIGS. 5A and 5B. Specifically, the substrate 610 includes an aluminum nitride layer 621 with an aluminum oxide bonding layer 631 formed thereon. Similarly, an additional aluminum oxide bonding layer 661 is formed on an additional aluminum nitride layer 651 disposed on the second substrate 640.

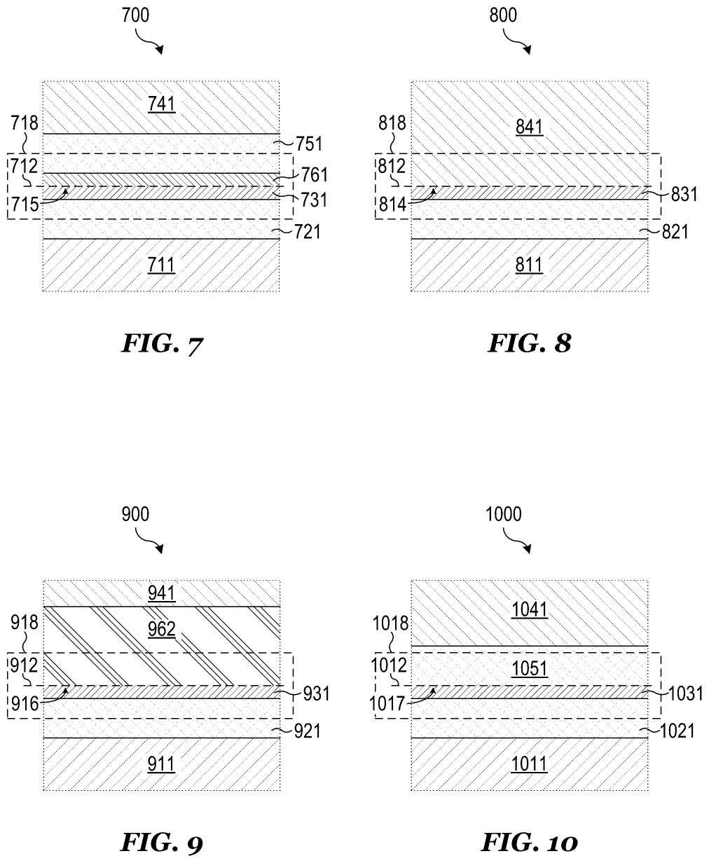

The aluminum oxide bonding layer 631 and the additional aluminum oxide bonding layer 661 are brought into contact at a bonding interface 612 to bond the substrate 610 to the second substrate 640 and form a bonded substrate structure. In this specific example, the bonding region 618 includes an aluminum oxide region (formed by bonding the aluminum oxide bonding layer 631 and the additional aluminum oxide bonding layer 661 together, which may or may not leave a discernible seam or bonding region) that is between two aluminum nitride regions (from the aluminum nitride layer 621 and the additional aluminum nitride layer 651). However, as will be explained in more detail in FIGS. 7-10, the material composition may vary depending the specific details of a given application.

Direct bonding processes, such as the direct bonding process 600, may include a number of steps that are performed to attain a bonded substrate structure (e.g., a bonded wafer structure as in W2 W processes or a hybrid bonded structure as in D2 W processes). Prior to bonding, the surfaces of the aluminum oxide bonding layer 631 and the additional aluminum oxide bonding layer 661 may be subjected to a surface activation plasma treatment (which may be a nitrogen plasma when aluminum oxide is used, as here) that is followed by rinse (e.g., with DI water) form hydrophilic groups on the exposed surfaces.

The substrates are then aligned face to face and bonded together using van der Waals forces. This process involves bringing the two substrates together and initiating a bond front by striking a region of the upper chuck holding the upper substrate with a striker. The forces of the strike causes the upper substrate to bond with the lower substrate locally, and then the bond front propagates across the substrates. This process may be performed in an ambient environment, or may be performed in vacuum to avoid back pressure from stopping the bonding and introducing voids.

If the surfaces of the substrates being bonded are too rough, the bonding results in the formation of voids (even in vacuum), which causes in poor bond quality (low bond strength). In other words, the bond energy of the bonded assembly may be sufficiently low to allow undesirable separation of the substrates during subsequent processing or during the product lifetime. Because of the smoother surface of the aluminum oxide bonding layer 631 and the additional aluminum oxide bonding layer 661, a void free bond interface may be formed. Embodiments with bonding energy greater than 2.5 J/m² may be formed using embodiments discussed in this application.

Various post-bonding processes may also be performed, such as involving flipping the bonded substrate structure (e.g., the bonded wafers) and thinning and etching the surfaces of the bonded assembly. Other steps may also be performed, such as via formation, wafer dicing, and so on.

FIG. 7 illustrates a cross-sectional view of an example bonded substrate structure with a bonding region that includes an aluminum oxide region between two aluminum nitride regions in accordance with embodiments of the invention. The bonded substrate structure of FIG. 7 may be a specific example of other bonded substrate structures described herein, such as the bonded substrate structure of FIG. 3, for example. Similarly labeled elements may be as previously described.

Referring to FIG. 7, a bonded substrate structure 700 includes a silicon substrate 711 (i.e., a first substrate) that is bonded to a second silicon substrate 741 using a bonding region 718 that includes an aluminum oxide region between two aluminum nitride regions. Specifically, the silicon substrate 711 includes an aluminum nitride layer 721 and an aluminum oxide bonding layer 731 while the second silicon substrate 741 also includes an additional aluminum nitride layer 751 and an additional aluminum oxide bonding layer 761. The aluminum oxide bonding layer 731 and the additional aluminum oxide bonding layer 761 are brought together at a bonding interface 712 to form the bonded substrate structure 700. In this case, the bonding surface of the second silicon substrate 741 is an aluminum oxide surface 715. The bonded substrate structure 700 is a specific example of the bonded substrate structure 300 of FIG. 3.

FIG. 8 illustrates a cross-sectional view of an example bonded substrate structure with a bonding region that includes an aluminum oxide region between a silicon-containing region and an aluminum nitride region in accordance with embodiments of the invention. The bonded substrate structure of FIG. 8 may be a specific example of other bonded substrate structures described herein, such as the bonded substrate structure of FIG. 1, for example. Similarly labeled elements may be as previously described.

Referring to FIG. 8, a bonded substrate structure 800 includes a silicon substrate 811 (i.e., a first substrate) that is bonded to a second silicon substrate 841 using a bonding region 818 that includes an aluminum oxide region between a silicon-containing region and an aluminum nitride region. Specifically, the silicon substrate 811 includes an aluminum nitride layer 821 and an aluminum oxide bonding layer 831 while the second silicon substrate 841 includes a silicon-containing surface 814. The aluminum oxide bonding layer 831 is brought into contact with the silicon-containing surface 814 at a bonding interface 812 to form the bonded substrate structure 800. The bonded substrate structure 800 is a specific example of the bonded substrate structure 100 of FIG. 1.

The silicon-containing surface 814 may be various silicon-containing materials. In various embodiments, the silicon-containing surface 814 is silicon and the second silicon substrate 841 includes a backside power distribution network (BSPDN) in one embodiment. In another embodiment, the silicon-containing surface 814 is silicon oxide. In still another embodiment, the silicon-containing surface 814 is silicon nitride. In yet another embodiment, the silicon-containing surface 814 is silicon carbide. In still yet another embodiment, the silicon-containing surface 814 is silicon carbonitride.

FIG. 9 illustrates a cross-sectional view of an example bonded substrate structure with a bonding region that includes an aluminum oxide region between a silicon oxide region and an aluminum nitride region in accordance with embodiments of the invention. The bonded substrate structure of FIG. 9 may be a specific example of other bonded substrate structures described herein, such as the bonded substrate structure of FIG. 1, for example. Similarly labeled elements may be as previously described.

Referring to FIG. 9, a bonded substrate structure 900 includes a silicon substrate 911 (i.e., a first substrate) that is bonded to a second silicon substrate 941 using a bonding region 918 that includes an aluminum oxide region between a silicon oxide region and an aluminum nitride region. Specifically, the silicon substrate 911 includes an aluminum nitride layer 921 and an aluminum oxide bonding layer 931 while the second silicon substrate 941 includes a silicon oxide layer 962. The aluminum oxide bonding layer 931 is brought into contact with the silicon oxide layer 962 at a bonding interface 912 to form the bonded substrate structure 900. In this case, the bonding surface is a silicon oxide surface 916, which is specific example of a silicon-containing surface. The bonded substrate structure 900 is a specific example of the bonded substrate structure 800 of FIG. 8.

FIG. 10 illustrates a cross-sectional view of another example bonded substrate structure with a bonding region that includes an aluminum oxide region between two aluminum nitride regions in accordance with embodiments of the invention. The bonded substrate structure of FIG. 10 may be a specific example of other bonded substrate structures described herein, such as the bonded substrate structure of FIG. 1, for example. Similarly labeled elements may be as previously described.

Referring to FIG. 10, a bonded substrate structure 1000 includes a silicon substrate 1011 (i.e., a first substrate) that is bonded to a second silicon substrate 1041 using a bonding region 1018 that includes an aluminum oxide region between two aluminum nitride regions. Specifically, the silicon substrate 1011 includes an aluminum nitride layer 1021 and an aluminum oxide bonding layer 1031 while the second silicon substrate 1041 also includes an additional aluminum nitride layer 1051. The aluminum oxide bonding layer 1031 and the additional aluminum nitride layer 1051 are brought together at a bonding interface 1012 to form the bonded substrate structure 1000. In this case, the bonding surface of the second silicon substrate 1041 is an aluminum nitride surface 1017. The bonded substrate structure 1000 is a specific example of the bonded substrate structure 100 of FIG. 1.

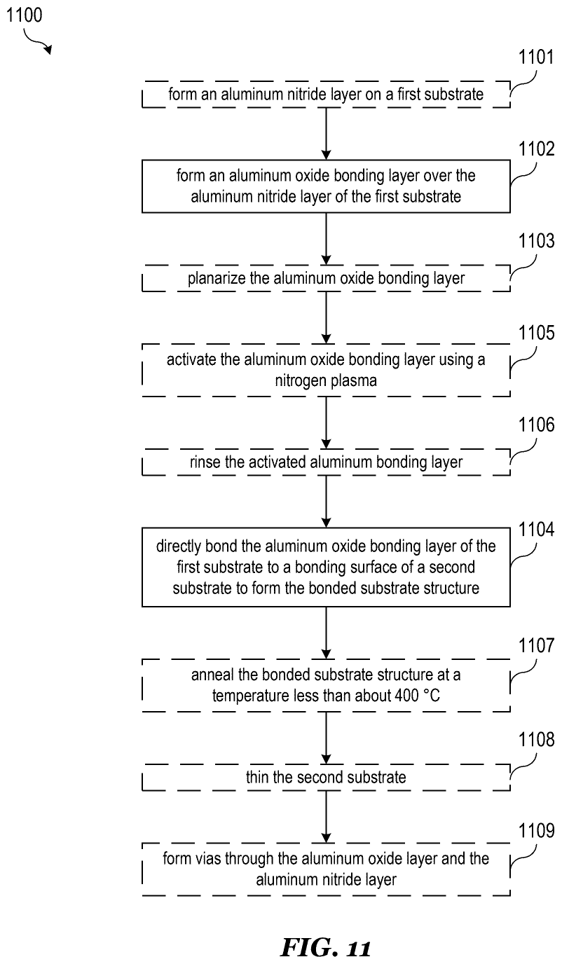

FIG. 11 illustrates an example method of forming a bonded substrate structure in accordance with embodiments of the invention. The method of FIG. 11 may incorporate any steps of the example direct bonding processes described herein, such as in FIGS. 4A-4B, 5A-5B, and 6. Further, the method of FIG. 11 may be used to form any of the bonded substrate structures described herein, such as in FIGS. 1, 3, and 7-10.

Referring to FIG. 11, a method 1100 of forming a bonded substrate structure includes a layer formation step 1102 during which an aluminum oxide bonding layer is formed over an aluminum nitride layer of a first substrate. For example, the aluminum oxide bonding layer may be formed using a deposition process such as ALD or CVD. After the layer formation step 1102, the aluminum oxide bonding layer of the first substrate is directly bonded to a bonding surface of a second substrate to form the bonded substrate structure during a direct bonding step 1104.

Various optional steps may also be included in the method 1100 as shown. For example, before, the layer formation step 1102, another optional layer formation step 1101 may be included to form an aluminum nitride layer on the first substrate. For example, the aluminum nitride layer may be formed using a deposition process such as PVD or CVD. Alternatively, as discussed elsewhere, the thermally conductive material may also be substituted for aluminum nitride, such as diamond for example.

In some embodiments, the aluminum oxide bonding layer is formed with sufficient smoothness to perform the direct bonding. However, in other embodiments, a planarization step 1103 may optionally be included to planarize the aluminum oxide bonding layer. For example, the planarization step 1103 may include CMP, ion milling, GCIB, or a combination thereof.

Additional treatment steps may be performed on the aluminum oxide bonding layer before the direct bonding step 1104, such as to enable room temperature bonding or a lower annealing temperature. For example, a nitrogen surface activation step 1105 during which the aluminum oxide bonding layer is activated using a nitrogen plasma. The activated aluminum oxide bonding layer (i.e., the activated surface) may then be rinsed during a rinsing step 1106. The rinsing step 1106 may include rinsing with DI water to form hydrophilic sites, such as hydroxyl sites.

After the direct bonding step 1104, the first and second substrates may be covalently bonded. Alternatively, the direct bonding step 1104 may only result void-free van der Waals bonding. In this case an annealing step 1107 may be included after the direct bonding step 1104 to form covalent bonds between the aluminum oxide bonding layer and the bonding surface of the second substrate. For example, the bonded substrate structure is annealed at a temperate less than about 400° C. in various embodiments, and is annealed at a temperate between about 100° C. and about 300° C. in some embodiments.

Further processes may also be performed in the bonded substrate structure.

Optionally, the second substrate may be thinned during a thinning step 1108. As another option, a via formation step 1109 may be included to form vias through the aluminum oxide bonding layer and the aluminum nitride layer. For example, the vias may extend from the bonding interface towards (and may be in communication with) active components in the second substrate.

Example embodiments of the invention are described below. Other embodiments can also be understood from the entirety of the specification as well as the claims filed herein.

Example 1. A bonded substrate structure includes a first substrate; a second substrate; and a bonding region bonding the first substrate to the second substrate. The bonding region includes an aluminum oxide bonding layer directly contacting an aluminum nitride layer, and a bonding interface between the aluminum oxide bonding layer and a bonding surface of the first substrate or the second substrate.

Example 2. The bonded substrate structure according to example 1, where the bonding surface is a silicon-containing surface.

Example 3. The bonded substrate structure according to one of examples 1 or 2, where the silicon-containing surface is a silicon surface.

Example 4. The bonded substrate structure according to one of examples 1 to 3, where the silicon-containing surface is a silicon dioxide surface.

Example 5. The bonded substrate structure according to one of examples 1 to 4, where the aluminum nitride layer has a thickness greater than about 25 nm, and where the aluminum oxide bonding layer has a thickness less than about 10 nm.

Example 6. The bonded substrate structure according to one of examples 1 to 5, where the bonding surface is an aluminum oxide surface.

Example 7. The bonded substrate structure according to one of examples 1 to 6, where the bonding region further includes an additional aluminum nitride layer on a first side of the bonding interface, the aluminum nitride layer being on an opposite second side of the bonding interface.

Example 8. A method of forming a bonded substrate structure includes forming an aluminum oxide bonding layer over an aluminum nitride layer of a first substrate; and directly bonding the aluminum oxide bonding layer of the first substrate to a bonding surface of a second substrate to form the bonded substrate structure.

Example 9. The method according to example 8, further includes activating the aluminum oxide bonding layer using a nitrogen plasma before directly bonding the aluminum oxide bonding layer to the bonding surface; and annealing the bonded substrate structure at a temperature less than about 400° C.

Example 10. The method according to one of examples 8 or 9, further includes planarizing the aluminum oxide bonding layer before directly bonding the aluminum oxide bonding layer to the bonding surface.

Example 11. The method according to one of examples 8 to 10, where the aluminum nitride layer has a thickness greater than about 25 nm, and where the aluminum oxide bonding layer has a thickness less than about 5 nm.

Example 12. The method according to one of examples 8 to 11, where forming the aluminum oxide bonding layer includes forming the aluminum oxide bonding layer directly on the aluminum nitride layer.

Example 13. The method according to one of examples 8 to 12, where the bonding surface is an aluminum oxide surface.

Example 14. The method according to one of examples 8 to 13, where the bonding surface is a silicon-containing surface.

Example 15. A method of forming a bonded substrate structure includes forming an aluminum oxide bonding layer directly on a thermally conductive and electrically insulating layer of a first substrate; activating the aluminum oxide bonding layer using a nitrogen plasma; and directly bonding the aluminum oxide bonding layer of the first substrate to a bonding surface of a second substrate to form the bonded substrate structure; and annealing the bonded substrate structure at a temperature less than 400° C.

Example 16. The method according to example 15, where the thermally conductive and electrically insulating layer is an aluminum nitride layer.

Example 17. The method according to one of examples 15 or 16, where the thermally conductive and electrically insulating layer is a diamond layer.

Example 18. The method according to one of examples 15 to 17, further includes planarizing the aluminum oxide bonding layer before directly bonding the aluminum oxide bonding layer to the bonding surface.

Example 19. The method according to one of examples 15 to 18, where the bonding surface is an aluminum oxide surface.

Example 20. The method according to one of examples 15 to 19, where the bonding surface is a silicon-containing surface.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A bonded substrate structure comprising:
a first substrate;
a second substrate; and
a bonding region bonding the first substrate to the second substrate, the bonding region comprising an aluminum oxide bonding layer directly contacting an aluminum nitride layer, and a bonding interface between the aluminum oxide bonding layer and a bonding surface of the first substrate or the second substrate.

2. The bonded substrate structure according to claim 1, wherein the bonding surface is a silicon-containing surface.

3. The bonded substrate structure according to claim 2, wherein the silicon-containing surface is a silicon surface.

4. The bonded substrate structure according to claim 2, wherein the silicon-containing surface is a silicon dioxide surface.

5. The bonded substrate structure according to claim 1, wherein the aluminum nitride layer has a thickness greater than about 25 nm, and wherein the aluminum oxide bonding layer has a thickness less than about 10 nm.

6. The bonded substrate structure according to claim 5, wherein the bonding surface is an aluminum oxide surface.

7. The bonded substrate structure according to claim 6, wherein the bonding region further comprises an additional aluminum nitride layer on a first side of the bonding interface, the aluminum nitride layer being on an opposite second side of the bonding interface.

8. A method of forming a bonded substrate structure, the method comprising:
forming an aluminum oxide bonding layer over an aluminum nitride layer of a first substrate; and
directly bonding the aluminum oxide bonding layer of the first substrate to a bonding surface of a second substrate to form the bonded substrate structure.

9. The method according to claim 8, further comprising:
activating the aluminum oxide bonding layer using a nitrogen plasma before directly bonding the aluminum oxide bonding layer to the bonding surface; and
annealing the bonded substrate structure at a temperature less than about 400° C.

10. The method according to claim 8, further comprising:
planarizing the aluminum oxide bonding layer before directly bonding the aluminum oxide bonding layer to the bonding surface.

11. The method according to claim 8, wherein the aluminum nitride layer has a thickness greater than about 25 nm, and wherein the aluminum oxide bonding layer has a thickness less than about 5 nm.

12. The method according to claim 8, wherein forming the aluminum oxide bonding layer comprises forming the aluminum oxide bonding layer directly on the aluminum nitride layer.

13. The method according to claim 8, wherein the bonding surface is an aluminum oxide surface.

14. The method according to claim 8, wherein the bonding surface is a silicon-containing surface.

15. A method of forming a bonded substrate structure, the method comprising:
forming an aluminum oxide bonding layer directly on a thermally conductive and electrically insulating layer of a first substrate;
activating the aluminum oxide bonding layer using a nitrogen plasma; and
directly bonding the aluminum oxide bonding layer of the first substrate to a bonding surface of a second substrate to form the bonded substrate structure; and
annealing the bonded substrate structure at a temperature less than 400° C.

16. The method according to claim 15, wherein the thermally conductive and electrically insulating layer is an aluminum nitride layer.

17. The method according to claim 15, wherein the thermally conductive and electrically insulating layer is a diamond layer.

18. The method according to claim 15, further comprising:
planarizing the aluminum oxide bonding layer before directly bonding the aluminum oxide bonding layer to the bonding surface.

19. The method according to claim 15, wherein the bonding surface is an aluminum oxide surface.

20. The method according to claim 15, wherein the bonding surface is a silicon-containing surface.
